(19) United States
(12) Patent Application Publication
(10) Pub. No.: US 2025/0306082 A1
(43) Pub. Date: Oct. 2, 2025

(54) TESTING JIG AND METHOD FOR TESTING AT LEAST ONE ASSEMBLY INCLUDING CIRCUIT BOARD AND LASERS THEREON

(71) Applicant: Global Technology Inc., Ningbo (CN)

(72) Inventors: Chao-Hung TSAI, Ningbo (CN); Jian-Hong LUO, Ningbo (CN); Qilin HONG, Ningbo (CN); Jizeng DING, Ningbo (CN)

(21) Appl. No.: 18/740,103

(22) Filed: Jun. 11, 2024

(30) Foreign Application Priority Data
Mar. 27, 2024 (CN) 202410357440.6

(51) Int. Cl. G01R 31/28

(52) U.S. Cl. CPC G01R 31/2817; G01R 31/2808

(57) ABSTRACT

A testing jig and method for testing at least one circuit board assembly are provided. The testing jig includes a housing and at least one thermally conductive component. The housing has a circuit board accommodation space. The thermally conductive component is disposed on and thermally coupled to the housing and at least partially located in the circuit board accommodation space. The thermally conductive component is capable of contacting a circuit board and thermally coupled to a heat source.

### CROSS-REFERENCE TO RELATED APPLICATIONS

This application claims priority under 35 U.S.C. § 119 (a) on Patent Application No(s). 202410357440.6 filed in China on Mar. 27, 2024, the entire contents of which are hereby incorporated by reference.

### BACKGROUND

### 1. Technical Field

The present disclosure relates to a testing jig and a method for testing at least one circuit board assembly.

### 2. Related Art

Optical modules may be used to transmit and/or receive optical signals for various applications including, without limitation, internet data center, cable TV and fiber to the home (FTTH). Optical modules provide higher speeds and wider bandwidth over longer distances. In order to promote the compatibility of products in global optical internet and reduce the maintenance burden, organizations such as Multi-Source Agreement (MSA), Institute of Electrical and Electronics Engineers (IEEE) and Optical Internetworking Forum (OIF) have defined various form factors applicable to different signal transmission rates. These form factors include, without limitation, XFP, SFP, QSFP (Quad Small Form Factor Pluggable), QSFP-DD (Double Density), OSFP (Octal Small Form Factor Pluggable) and CPO (Co-Packaged Optics).

Current optical modules have presented challenges, for example, with respect to optical efficiency (power), space management, thermal management, insertion loss and manufacturing yield.

### SUMMARY

According to one aspect of the present disclosure, a testing jig is configured to support a circuit board assembly. The circuit board assembly includes a circuit board and a heat source disposed on a side of the circuit board. The testing jig includes a housing and at least one thermally conductive component. The housing has a circuit board accommodation space. The at least one thermally conductive component is disposed on and thermally coupled to the housing, and at least part of the at least one thermally conductive component is located in the circuit board accommodation space. The at least one thermally conductive component is capable of contacting with the circuit board and thermally coupled to the heat source.

According to another aspect of the present disclosure, a method for testing a plurality of circuit board assemblies includes: placing the plurality of circuit board assemblies into an oven, wherein each of the plurality of circuit board assemblies in the oven is in a standby state; obtaining a temperature value of each of the plurality of circuit board assemblies in the standby state via a temperature sensor of each of the plurality of circuit board assemblies; and selectively switching an on-off-state of at least one channel of at least one heat source of each of the plurality of circuit board assemblies in the standby state based on the temperature value of each of the plurality of circuit board assemblies.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a perspective view of a testing jig and a circuit board assembly according to one embodiment of the present disclosure;

FIG. 2 is an exploded view of the testing jig and the circuit board assembly in FIG. 1;

FIG. 3 is a top view of the testing jig and the circuit board assembly in FIG. 1;

FIG. 4 is a schematic cross-sectional view of the testing jig and the circuit board assembly taken along line 4-4 in FIG. 3;

FIG. 5 is a schematic cross-sectional view of the testing jig and the circuit board assembly taken along line 5-5 in FIG. 3;

FIG. 6 is a schematic view showing a method for testing a plurality of circuit board assemblies according to one embodiment of the present disclosure; and

FIG. 7 is a flow chart of a method for testing a plurality of circuit board assemblies according to one embodiment of the present disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

General, lasers such as Vertical Cavity Surface Emitting Laser (VCSEL), Directly Modulated Laser (DML) and Electroabsorption Modulated Laser (EML) that are packaged into a laser chip by, for example, chip on board (COB). The lasers tend to involve complex chip fabrication processes. Therefore, such lasers commonly have insufficient reliability and short lifespan.

In order to ensure the reliability and the lifespan of a laser, the laser needs to undergo a burn-in test before leaving the factory. During the burn-in test, a circuit board with the laser disposed thereon is placed into an oven and applied with a high current. However, such burn-in test has a large temperature error so that it cannot accurately screen out lasers with early failures or performance deficiencies. Furthermore, due to limitations in processes, it is difficult to directly measure the actual temperature of the laser during the burn-in test. Therefore, the temperature of the laser is typically indirectly monitored via a temperature sensor of the circuit board assembly. However, there is often a temperature difference between the temperature value measured by the temperature sensor and the actual temperature of the laser. Such temperature difference makes it difficult for the burn-in test to accurately screen out lasers with early failures or performance deficiencies. Specifically, such temperature difference is typically greater than 5 degrees Celsius.

According one embodiment of the present disclosure, in the testing jig, the thermally conductive component may be configured to be in contact with the circuit board and thermally coupled to the heat source. Therefore, the thermally conductive component may transfer the heat generated by the heat source to the housing so as to allow the temperature of the circuit board assembly to be uniform. As such, the temperature difference between the circuit board assembly and the heat source may be reduced, thereby accurately screening out heat sources with early failures or performance deficiencies. According to the actual test, by the testing jig according to the above embodiments, the temperature difference between the temperature measured by the temperature sensor of the circuit board and the actual temperature of the heat source such as a laser may be reduced to be within 1.5 degrees Celsius.

According to one embodiment of the present disclosure, in the method for testing at least one circuit board assembly, the on-off-state of a channel of a heat source of the circuit board assembly in a standby state may be selectively switched based on the temperature value of each circuit board assembly. The temperature of the circuit board assembly may be increased or decreased correspondingly by turning on or turning off the channel. Therefore, the switching of the on-off-state based on the temperature value as described above may reduce the temperature difference between the circuit board and the heat source, thereby accurately screening out lasers with early failures or performance deficiencies. According to the actual test, by the testing jig according to the above embodiments, the temperature difference between the temperature measured by the temperature sensor of the circuit board and the actual temperature may be reduced to be within 0.5 degrees Celsius.

According to the testing jig or the method of one embodiment of the present disclosure, the temperature difference between these heat sources may be reduced to be within 0.5 degrees Celsius, thereby further reducing the temperature difference between the circuit board and the heat source.

Some or all of technical features disclosed in one or more embodiments of the present disclosure may be combined and configured to achieve corresponding effects.

The term “coupled”, “coupling” or “couple” as used herein refers to any connection, link or the like. Such “coupled” components are not necessarily directly connected to one another and may be separated by intermediate components unless otherwise provided by the present disclosure.

The term “channel” as used herein refers to optical channel(s) for transmitting or receiving signals related to channel wavelength. The channel wavelengths may include a specified wavelength band around a center wavelength. In one example, the channel wavelengths may be defined by an International Telecommunication (ITU) standard such as the ITU-T course wavelength division multiplexing (CWDM) or dense wavelength division multiplexing (DWDM) grid.

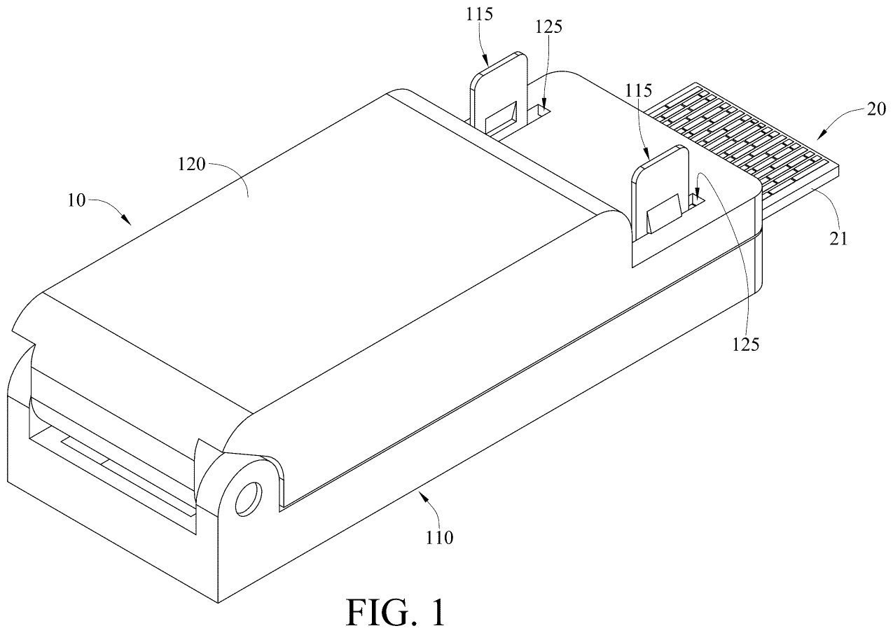

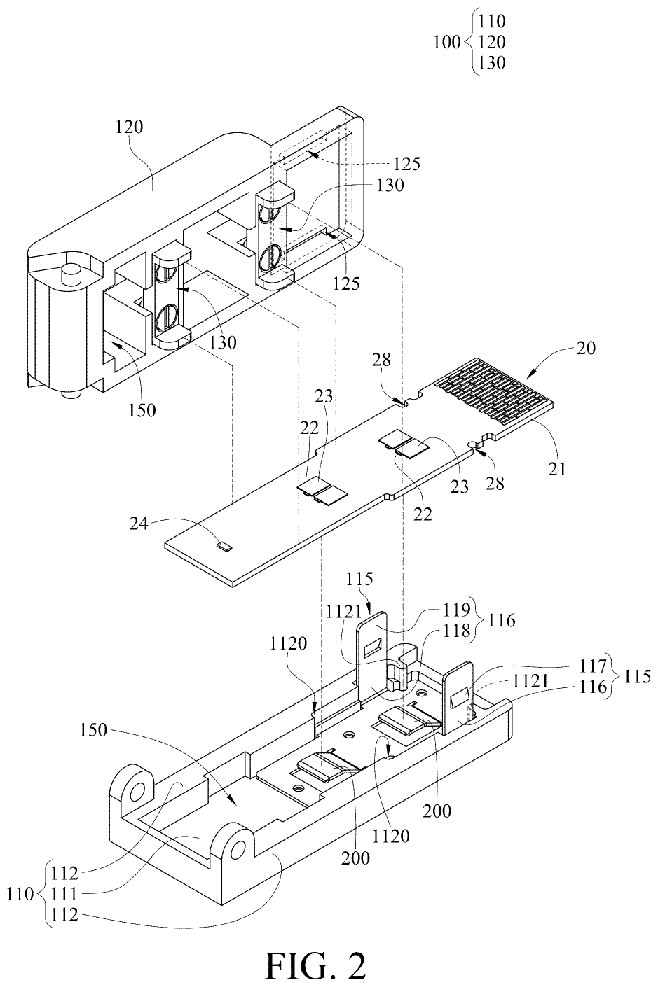

Please refer to FIG. 1 and FIG. 2. FIG. 1 is a perspective view of a testing jig 10 and a circuit board assembly 20 according to one embodiment of the present disclosure. FIG. 2 is an exploded view of the testing jig 10 and the circuit board assembly 20 in FIG. 1.

The testing jig 10 may be configured to support the circuit board assembly 20. The circuit board assembly 20 may include a circuit board 21 and a plurality of heat sources 22, a plurality of heat sources 23 and a temperature sensor 24 that are disposed on a side of the circuit board 21. The heat source 22 may be a laser, such as Vertical Cavity Surface Emitting Laser (VCSEL), Directly Modulated Laser (DML) and Electroabsorption Modulated Laser (EML). The heat source 23 may be a transimpedance amplifier (TIA). The temperature sensor 24 may be a thermistor and may monitor the temperature of the circuit board assembly 20 by digital diagnostic monitoring interface (DDMI).

In one embodiment, the circuit board assembly 20 may be a printed circuit board assembly (PCBA) used in an optical module such as optical transceiver. The lasers of the circuit board assembly 20 may be laser packages in a transmitter optical subassembly (TOSA) module for transmitting multiple channels using different channel wavelengths. The TIA may be electrically coupled to photodiodes of the circuit board assembly 20, and the TIA as well as the photodiode may configure a receiver optical subassembly (ROSA) module for receiving multiple channels using different channel wavelengths.

In one embodiment, the heat source 23 may be a laser diode driver (LDD) electrically coupled to the lasers of the circuit board assembly 20.

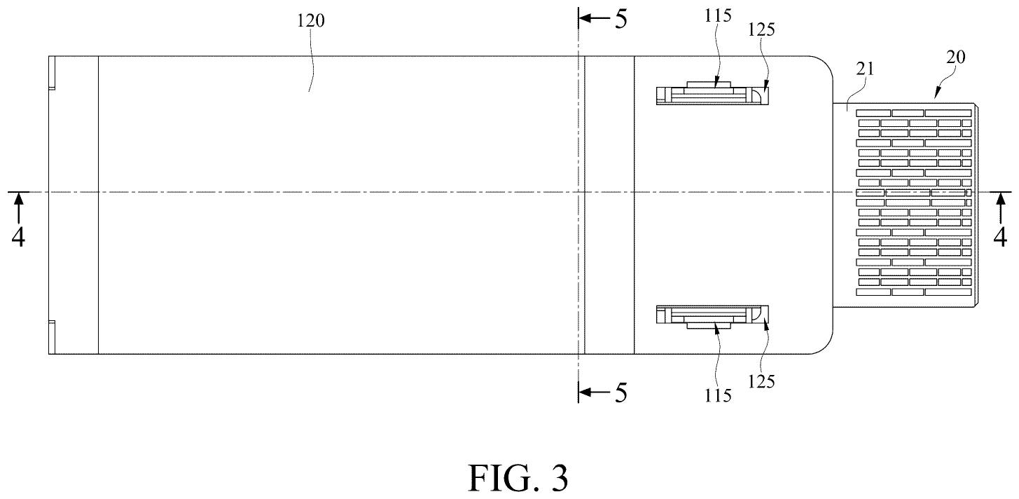

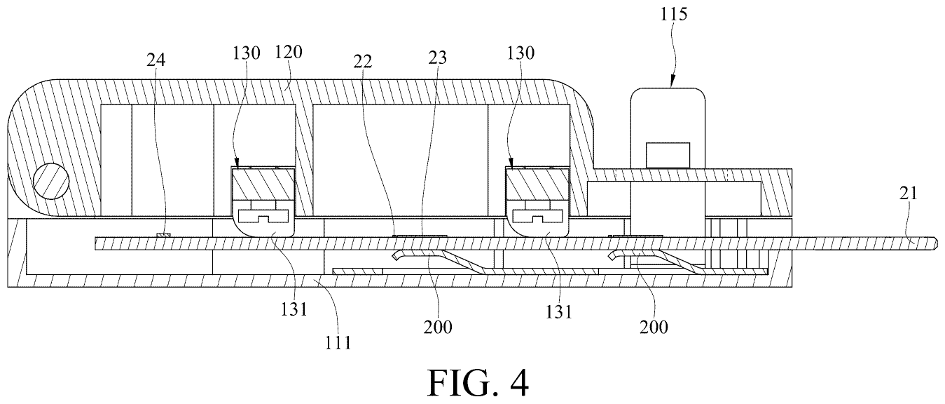

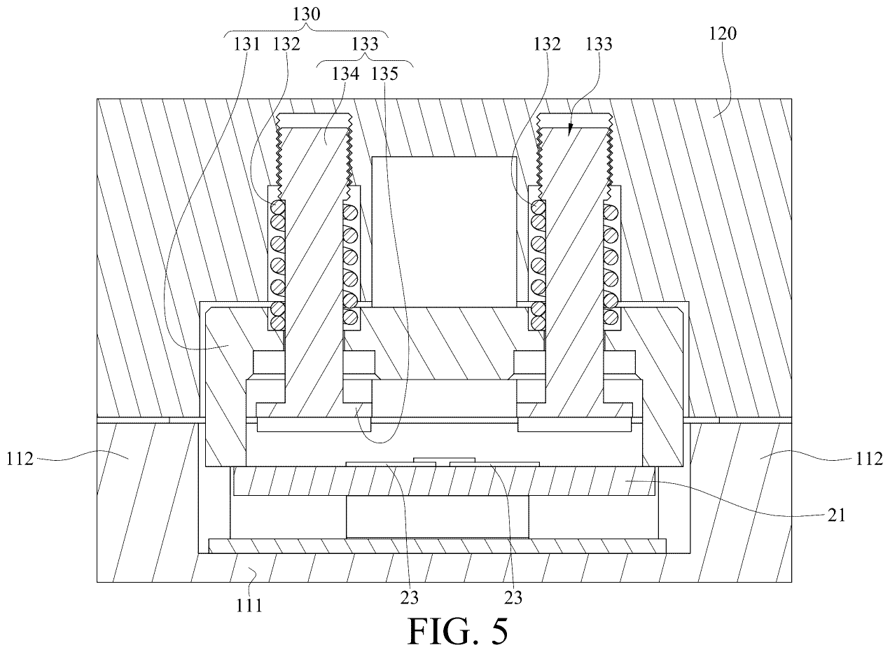

Please refer to FIG. 2 to FIG. 5. FIG. 3 is a top view of the testing jig 10 and the circuit board assembly 20 in FIG. 1. FIG. 4 is a schematic cross-sectional view of the testing jig 10 and the circuit board assembly 20 taken along line 4-4 in FIG. 3. FIG. 5 is a schematic cross-sectional view of the testing jig 10 and the circuit board assembly 20 taken along line 5-5 in FIG. 3.

The testing jig 10 may include a housing 100 and two thermally conductive components 200. The housing 100 may include a base 110, a pressing cover 120 and two pressing assemblies 130. The base 110 may include a bottom plate 111 and two side plates 112. The two side plates 112 may stand on opposite sides of the bottom plate 111, respectively.

In addition, in this embodiment, the two side plates 112 may each have a limiting recess 1120 for limiting the movement of the circuit board 21. Also, in this embodiment, the two side plates 112 may each have a positioning protrusion 1121 protruding therefrom, and the two positioning protrusions 1121 may be configured to be positioned in two positioning recesses 28 of the circuit board 21, respectively. By the design of the limiting recesses 1120 and the positioning protrusions 1121, it may be further ensured that the circuit board 21 is fixed on the testing jig 10 at the desired position. In other embodiments, the limiting recesses 1120 and the positioning protrusions 1121 may be omitted.

The pressing cover 120 may be movably disposed on the two side plates 112. When the pressing cover 120 is closed on or covered on the base 110, the pressing cover 120 may be abutted against the two side plates 112, and the pressing cover 120, the bottom plate 111 and the two side plates 112 may together form a circuit board accommodation space 150. The circuit board accommodation space 150 may accommodate at least a part of the circuit board 21 therein.

The pressing assembly 130 may be located in the circuit board accommodation space 150, and the pressing cover 120 may press the circuit board 21 via the pressing assembly 130. The pressing assembly 130 may include a pressing plate 131, two elastic components 132 and two limiting pins 133. The pressing plate 131 may be movably disposed on the pressing cover 120 via the two elastic components 132. The pressing plate 131 may be roughly in, for example, an U-shape and may be configured to press the circuit board 21. The two elastic components 132 may be sleeved on the two limiting pins 133, respectively. The limiting pin 133 may include a fixed end part 134 and a limiting end part 135 opposite to each other. The fixed end part 134 may be fixed to the pressing cover 120. A part of the pressing plate 131 may be located between the limiting end part 135 and pressing cover 120, and the movement of the pressing plate 131 may be limited by the limiting end part 135.

The two thermally conductive components 200 may be spaced apart from each other and may be elastic fasteners. The thermally conductive component 200 may be disposed on and thermally coupled to the housing 100. In detail, the thermally conductive component 200 may protrude from the bottom plate 111 and may be at least partially located in the circuit board accommodation space 150. In this embodiment, the thermally conductive component 200 and the base 110 may be integrally formed as a single piece. The thermally conductive component 200 may be configured to be in contact with a side of the circuit board 21 located farthest away from the heat sources 22 and 23, and may be thermally coupled to the heat sources 22 and 23. In other embodiments, the thermally conductive component may be in contact with a side of the circuit board where the heat sources are disposed.

In addition, the thermal conductivity of the base 110 and the thermal conductivity of the thermally conductive component 200 may be greater than the thermal conductivity of the pressing cover 120. Therefore, the heat generated by the heat sources 22 and 23 can be more effectively transferred to the base 110 and the thermally conductive component 200.

In addition, when the pressing cover 120 is closed on or covered on the base 110, the pressing cover 120 may be configured to press the circuit board 21 to ensure a physical contact between the thermally conductive component 200 and the circuit board 21. By the design of the pressing assembly 130, the tight contact between the thermally conductive component 200 and the circuit board 21 is ensured so that the heat generated by the heat sources 22 and 23 may be transferred to the thermally conductive component 200 more effectively.

In this embodiment, the base 110 may have two first positioning structures 115, and the pressing cover 120 may have two second positioning structures 125. The first positioning structure 115 may include an elastic arm 116 and an engaging protrusion 117. The elastic arm 116 may include a fixed end part 118 and a movable end part 119 opposite to each other. The fixed end part 118 may be fixed to the base 110. For example, the fixed end part 118 may stand on the bottom plate 111. The engaging protrusion 117 may protrude from the movable end part 119. The second positioning structure 125 may be an engaging hole. When the pressing cover 120 is closed on or covered on the base 110, the two engaging protrusions 117 may be configured to be engaged to the two second positioning structures 125 to prevent the pressing cover 120 from being opened relative to the base 110.

The thermally conductive component 200 may be configured to be in contact with the circuit board 21 and thermally coupled to the heat sources 22 and 23. Therefore, the thermally conductive component 200 may transfer the heat generated by the heat sources 22 and 23 to the housing 100 so as to allow the temperature of the circuit board 21 to be uniform. As such, the temperature difference between the temperature measured by the temperature sensor 24 on the circuit board 21 and the actual temperature of the heat source 22 may be reduced, thereby accurately screening out the heat source 22 with early failures or performance deficiencies.

In addition, the base 110 may fix the circuit board assembly 20 to a desired position so that the circuit board assembly 20 may be connected to an external electrical connector (not shown).

In addition, since both of the thermally conductive component 200 and the first positioning structure 115 may be in an elastic fastener form, they may have advantages of stable and reliable structures and may achieve an effect of repeated use without failure.

In addition, the thermally conductive component 200 in an elastic fastener form may be in tight contact with the circuit board 21 to increase the efficiency of transferring the heat generated by the heat sources 22 and 23 to the thermally conductive component 200. In one embodiment, the thermally conductive component 200 may include a metal clip or a spring plate. In this embodiment or other embodiments, a thermally conductive medium, such as a thermally conductive pad, may be added between the thermally conductive component 200 and the circuit board 21 to further increase the efficiency of transferring the heat generated by the heat sources 22 and 23 to the thermally conductive component 200.

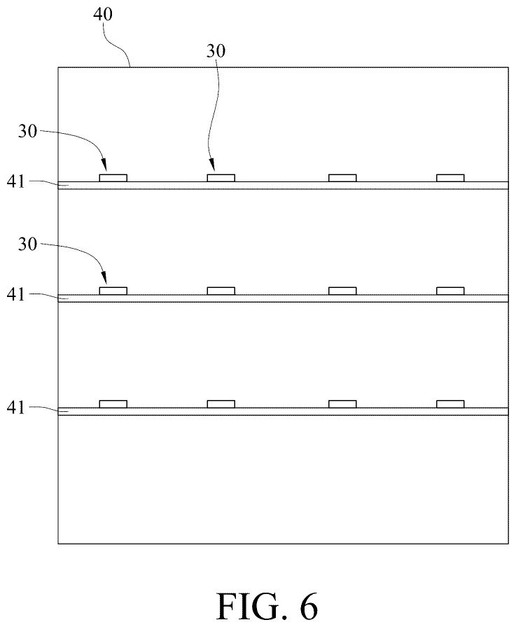

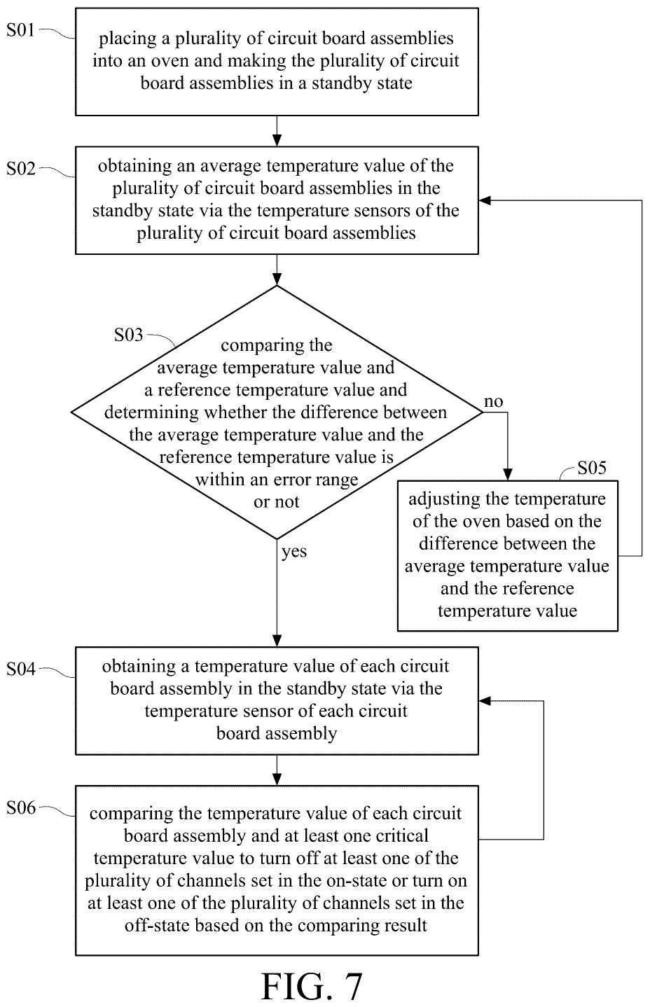

Please refer to FIF. 2, FIG. 6 and FIG. 7. FIG. 6 is a schematic view showing a method for testing a plurality of circuit board assemblies according to one embodiment of the present disclosure. FIG. 7 is a flow chart of a method for testing a plurality of circuit board assemblies according to one embodiment of the present disclosure. The method for testing the circuit board assembly 20 in FIG. 1 may be a burn-in test and may include the following steps.

First, a step S01 may be performed to place a plurality of circuit board assemblies 20 into an oven 40, and to make the circuit board assemblies 20 to be in a standby state. In this embodiment, a plurality of testing objects 30 including the testing jig 10 and the circuit board assembly 20 may be placed on a plurality of shelves 41 in the oven 40, respectively. Furthermore, in this embodiment, the circuit board assembly 20 may be placed into the testing jig 10 to constitute a testing object 30, and then the testing object 30 is placed on the shelves 41 in the oven 40. In FIG. 6, for conciseness, the appearance of the testing object 30 including the testing jig 10 and the circuit board assembly 20 may be simplified. In this embodiment, the heat source 23 of each circuit board assembly 20 may have a plurality of channels. When the circuit board assembly 20 is in the standby state, in the heat source 23 of each circuit board assembly 20, some of the channels may be set in an on-state, and the other channel(s) may be set in an off-state. The on-state channel may allow transmission of signals via circuitry of the circuit board assembly 20 or optical passive components. The off-state channel may prohibit such transmission of signals.

Then, a step S02 may be performed to obtain an average temperature value of the plurality of circuit board assemblies 20 in the standby state via the temperature sensor 24 of the circuit board assembly 20. It should be noted that after the step S01 is performed, the step S02 may be performed after a period (for example, 20 minutes) to ensure that the oven 40 fully heat the circuit board assembly 20.

Then, a step S03 may be performed to adjust the temperature of the oven 40 based on the average temperature value. In detail, the average temperature value may be compared with a reference temperature value to determine whether the difference between the average temperature value and the reference temperature value is within an error range or not. If the difference between the average temperature value and the reference temperature value is within the error range, a step S04 may be performed to obtain a temperature value of each circuit board assembly 20 in the standby state via the temperature sensor 24 of each circuit board assembly 20. If the difference between the average temperature value and the reference temperature value is out of the error range, a step S05 may be performed to adjust the temperature of the oven 40 based on the difference between the average temperature value and the reference temperature value, and then the step S02 may be performed again. It should be noted that after the step S05 is performed, the step S02 may be performed again after a period (for example, 20 minutes) to ensure that the oven 40 fully heat the circuit board assembly 20.

The steps S03 and S05 may ensure that the oven 40 controls the temperature of the circuit board assembly 20 to be in the range close to the reference temperature value. However, in other embodiments, if the difference between the temperature of the oven and the temperature of the circuit board assembly is small, the steps S03 and S05 may be omitted.

After the step S04 is performed, a step S06 may be then performed to selectively switch the on-off-state of the channel of the heat source 23 of each circuit board assembly 20 in the standby state based on the temperature value of each circuit board assembly 20. In detail, the temperature value of each circuit board assembly 20 may be compared with at least one critical temperature value, and at least one of the plurality of channels set in the on-state may be turned off or at least one of the plurality of channels set in the off-state may be turned on based the comparing result. The temperature of the circuit board assembly may be increased or decreased correspondingly by turning on or turning off the channel. Therefore, the switching of the on-off-state based on the temperature value as described above may reduce the temperature difference between the temperature measured by the temperature sensor 24 on the circuit board 21 and the actual temperature of the heat source 22, thereby accurately screening out heat sources 22 with early failures or performance deficiencies. Since different channels in the heat source 23 in one circuit board assembly 20 may generate different amounts of heat, different channels may be compared with different critical temperature values to more accurately control the temperature of the circuit board assembly 20 by switching the on-off-state.

In this embodiment, since it may be the heat source 23 as a transimpedance amplifier that undergoes the switching of the on-off-state of the channel, the heat source 22 as a laser may be accurately tested without affecting the operation of the heat source 22 as a laser.

In addition, the steps S04 and S05 may be repeated until the temperature value of each circuit board assembly 20 in the standby state is adjusted to be within a desired error range based on the switching of the on-off-state of the channel.

It should be noted that in other embodiments, the temperature of a single circuit board assembly may also be adjusted by switching the on-off-state of a single channel of a single heat source of the single circuit board assembly.

The embodiments are chosen and described in order to best explain the principles of the present disclosure and its practical applications, to thereby enable others skilled in the art to best utilize the present disclosure and various embodiments with various modifications as are suited to the particular use being contemplated. It is intended that the scope of the present disclosure is defined by the following claims and their equivalents.

What is claimed is:

1. A testing jig, configured to support a circuit board assembly comprising a circuit board and a heat source disposed on a side of the circuit board, the testing jig comprising:
a housing, having a circuit board accommodation space; and
at least one thermally conductive component, disposed on and thermally coupled to the housing, wherein at least part of the at least one thermally conductive component is located in the circuit board accommodation space; and
wherein the at least one thermally conductive component is capable of contacting the circuit board and thermally coupled to the heat source.

2. The testing jig of claim 1, wherein the at least one thermally conductive component is capable of contacting a side of the circuit board located away from the heat source.

3. The testing jig of claim 1, wherein the at least one thermally conductive component is an elastic fastener.

4. The testing jig of claim 1, wherein the housing comprises a base and a pressing cover, the pressing cover is movably disposed on the base, the pressing cover and the base jointly form the circuit board accommodation space, the at least one thermally conductive component protrudes from the base, and
when the pressing cover is closed on the base, the pressing cover is capable of pressing the circuit board to ensure a physical contact between the at least one thermally conductive component and the circuit board.

5. The testing jig of claim 4, wherein the base comprises a bottom plate and two side plates, the two side plates stand on opposite sides of the bottom plate, respectively, and
when the pressing cover is closed on the base, the pressing cover is abutted against the two side plates, and the at least one thermally conductive component protrudes from the bottom plate.

6. The testing jig of claim 4, wherein the base has at least one first positioning structure, the pressing cover has at least one second positioning structure, and
when the pressing cover is closed on the base, the at least one first positioning structure and the at least one second positioning structure are positioned with each other to prevent the pressing cover from being opened relative to the base.

7. The testing jig of claim 6, wherein the at least one first positioning structure comprises an elastic arm and an engaging protrusion, the elastic arm comprises a fixed end part and a movable end part opposite to each other, the fixed end part is fixed to the base, the engaging protrusion protrudes from the movable end part, the at least one second positioning structure is an engaging hole, and when the pressing cover is closed on the base, the engaging protrusion is configured to be engaged with the at least one second positioning structure.

8. The testing jig of claim 4, wherein a thermal conductivity of the base and a thermal conductivity of the at least one thermally conductive component are greater than a thermal conductivity of the pressing cover.

9. The testing jig of claim 4, wherein the housing further comprises at least one pressing assembly, the at least one pressing assembly is disposed on the pressing cover and located in the circuit board accommodation space, and the pressing cover is capable of pressing the circuit board via the at least one pressing assembly.

10. The testing jig of claim 9, wherein the at least one pressing assembly comprises a pressing plate, an elastic component and at least one limiting pin, the pressing plate is movably disposed on the pressing cover via the elastic component, the pressing plate is capable of pressing the circuit board, the limiting pin comprises a fixed end part and a limiting end part opposite to each other, the fixed end part is fixed to the pressing cover, and a part of the pressing plate is located between the limiting end part and the pressing cover and a movement of the pressing plate is limited by the limiting end part.

11. A method for testing a plurality of circuit board assemblies, comprising:
placing the plurality of circuit board assemblies into an oven, wherein each of the plurality of circuit board assemblies in the oven is in a standby state;
obtaining a temperature value of each of the plurality of circuit board assemblies in the standby state via a temperature sensor of each of the plurality of circuit board assemblies; and
selectively switching an on-off-state of at least one channel of at least one heat source of each of the plurality of circuit board assemblies in the standby state based on the temperature value of each of the plurality of circuit board assemblies.

12. The method of claim 11, wherein before obtaining the temperature value of each of the plurality of circuit board assemblies in the standby state via the temperature sensor of each of the plurality of circuit board assemblies, the method further comprises:
obtaining an average temperature value of the plurality of circuit board assemblies in the standby state via the temperature sensors of the plurality of circuit board assemblies; and
adjusting the temperature of the oven based on the average temperature value.

13. The method of claim 12, wherein adjusting the temperature of the oven based on the average temperature value comprises:
comparing the average temperature value and a reference temperature value, if a difference between the average temperature value and the reference temperature value is within an error range, the temperature value of each of the plurality of circuit board assemblies in the standby state is obtained via the temperature sensor of each of the plurality of circuit board assemblies; if the difference between the average temperature value and the reference temperature value is out of the error range, the temperature of the oven is adjusted based on the difference between the average temperature value and the reference temperature value and the average temperature value of the plurality of circuit board assemblies in the standby state is obtained via the temperature sensors of the plurality of circuit board assemblies again.

14. The method of claim 11, wherein the at least one channel of the at least one heat source of each of the plurality of circuit board assemblies comprises a plurality of channels, when the plurality of circuit board assemblies are in the standby state, in the at least one heat source of each of the plurality of circuit board assemblies, some of the plurality of channels are set in an on-state, and some of the plurality of channels are set in an off-state;
selectively switching the on-off-state of the at least one channel of the at least one heat source of each of the plurality of circuit board assemblies in the standby state based on the temperature value of each of the plurality of circuit board assemblies comprises:
comparing the temperature value of each of the plurality of circuit board assemblies and at least one critical temperature value to turn off at least one of the plurality of channels set in the on-state or turn on at least one of the plurality of channels set in the off-state based on the comparing result.

15. The method of claim 11, wherein the at least one heat source of each of the plurality of circuit board assemblies is a transimpedance amplifier.

16. A method for testing at least one circuit board assembly, comprising:
placing the at least one circuit board assembly into an oven and making the at least one circuit board assembly in a standby state;
obtaining a temperature value of the at least one circuit board assembly in the standby state via a temperature sensor of the at least one circuit board assembly; and
selectively switching an on-off-state of at least one channel of at least one heat source of the at least one circuit board assembly in the standby state based on the temperature value.
